(19) United States
(12) Patent Application Publication
(10) Pub. No.: US 2025/0027827 A1
(43) Pub. Date: Jan. 23, 2025

(54) Pressure Sensitive Transistor Gated with Deep Eutectic Solvent Gel

(71) Applicant: Trustees of Tufts College, Medford, MA (US)

(72) Inventors: Sameer Sonkusale, Lincoln, MA (US); Rachel Owyeung, Medford, MA (US); Matthew Panzer, Medford, MA (US)

(21) Appl. No.: 18/716,562

(22) PCT Filed: Dec. 6, 2022
(86) PCT No.: PCT/US2022/051918

§ 371 Date: Jun. 5, 2024

Related U.S. Application Data
(60) Provisional application No. 63/286,259, filed on Dec. 6, 2021.

(51) Int. Cl. G01L 9/00; G01L 9/12

(52) U.S. Cl. CPC G01L 9/0072; G01L 9/12

(57) ABSTRACT

A transistor that has a capacitance that varies in response to pressure includes a gel coupled to a gate thereof. The gel comprises a eutectic mixture having ionic conductivity.

### RELATED APPLICATION

This application claims the benefit of the Dec. 6, 2021 priority date of U.S. Provisional Application 63/286,259, the contents of which are incorporated herein by reference.

### STATEMENT OF GOVERNMENT RIGHTS

This invention was made with government support under grant 1935555 awarded by the National Science Foundation. The government has certain rights in the invention.

### BACKGROUND

Many human senses have, to some extent, been replicated in machines. Machine-vision systems and microphones, for example, have come to replicate the senses of sight and hearing.

However, replicating the sense of touch has proven more elusive. Human skin, with its stretchability combined with high mechanical toughness, its ability to sense at low and medium pressures, and the ability to heal itself to a limited extent and to retain function when damaged, has been difficult to emulate.

Despite the technical difficulties in its construction, artificial skin would be useful for a variety of applications. For example, a robot with a sense of touch as sensitive as that of a human would be useful for quality control applications. A reading device with such properties would be able to detect steganographically encoded patterns in what would appear to simply be a rough surface. Such skins would also be useful for wearable devices or prosthetic devices.

A continuing challenge in creating artificial skin with tactile receptors is that of creating an array of devices that are sensitive to pressure.

### SUMMARY

The invention relies in part on the ability to measure pressure by varying capacitance. The sensitivity with which pressure can be measured thus depends in part on the extent to which a given pressure changes a capacitance. Thus, to measure pressure, it is useful to have a transistor whose capacitance varies with pressure applied to some portion of the transistor.

In one aspect, the invention features a transistor having a variable gate-electrode capacitance that modulates current flow from drain to source.

A suitable transistor is one in which the gate includes a gel electrolyte, and in particular, a gel that comprises a eutectic mixture having ionic conductivity.

The gel is disposed such that pressure on the gate deforms the gel. This increases its contact surface with the gate electrode. The resulting change in contact area causes a variation in capacitance of the interface between the gel and the gate electrode.

Among the embodiments are those in which the gel comprises a deep eutectic solvent. Such a gel is advantageous because of its low volatility, its dense population of ions, and its moderate ionic conductivity. Because of the gel's low volatility, the transistor is less prone to drying out. In addition, a deep eutectic gel can be formed using materials that are inexpensive and environmentally friendly. In addition, since the transistor is less prone to drying out, it is possible to use a substrate that is permeable to water vapor.

In one aspect, the transistor comprises an active channel coupled between drain and source terminals and gel electrolyte disposed above the active channel and coupled to a gate terminal.

In another aspect, the invention features a transistor having a capacitance that varies in response to pressure, the transistor comprising a deep eutectic electrolyte gel.

Among these are embodiments in which the transistor is integral with a thread and those in which the transistor is part of a transistor array on artificial skin.

Among the embodiments are those in which the transistor comprises a gate electrode that contacts the gel at a contact area. Pressure applied to the gate electrode deforms the gel, thus changing the contact area. This causes a change in the capacitance.

Also among the embodiments are those in which the transistor comprises a first capacitance and a second capacitance, the first capacitance being a capacitance of an interface between a gate terminal and the gel and the second capacitance being a capacitance of a conducting channel connected to a drain of the transistor. In such embodiments, the first capacitance varies in response to pressure.

An electrochemical transistor as described above offers a relatively high transconductance. As a result, a small change in the voltage at the gate causes a significant, and therefore easily measurable change in drain current.

In some embodiments, the transistor is integrated into a thread and as such can be made conformal to a variety of shapes.

In still other embodiments, the transistor comprises a body of gel that comprises a pressure-sensing region and a gate region. In such embodiments, the gate region is coupled to the gate. A force applied to the pressure-sensing region results in a change in an electrical characteristic at the pressure-sensing region. This change is communicated to the gate region as a result of long-range polarization of the gel. A pressure-sensitive region is thus usable as an artificial skin with tactile capability.

Still other embodiments include those in which the transistor comprises a protrusion that, upon being deformed in response to pressure applied to the protrusion, causes a change in the capacitance. Among these are embodiments in which the protrusion is one of many protrusions. These include embodiments in which the protrusions have different shapes and those in which they have the same shapes but different sizes, or heights. Such embodiments make it possible for the transistor to change capacitance by different amounts depending on where pressure is actually applied to the gate. Such embodiments also make it possible to control the capacitance's rate of change with respect to time and to do so also as a function of location at which pressure is applied.

Also among the embodiments are those in which the gate is coupled to an active channel that extends between a source and drain of the transistor. Among these are embodiments in which a conductive thread implements the active channel.

In some embodiments, the gate is coupled to active channels of the transistor, with the active channels being connected either in series or in parallel.

Of particular interest is an organic electrochemical transistor.

In other embodiments, the transistor includes a combination of poly (3, 4-ethylenedioxythiophene) and sodium polystyrene sulfonate. Other embodiments include those made of an inorganic material, including a semiconductor.

Embodiments further include those in which the transistor comprises an active channel that comprises one or more of: a semiconducting polymer, a doped conductor, an inorganic semiconductor, and an organic semiconductor.

Still other embodiments include those in which the electrolyte is an aqueous electrolyte. However, these embodiments are prone to deterioration as a result of evaporation. To reduce this tendency, other embodiments rely on a low-volatility electrolyte, such as an ionic liquid. However, these embodiments require additional salts in solution to achieve transistor action.

In other embodiments, the gel comprises a liquid component and a solid network that serves as a scaffold for the liquid component. The liquid component comprises a mixture that comprises a first substance and a second substance. The first and second substances have corresponding first and second phase-transition temperatures for transitioning between liquid and solid states. The first substance comprises ionic species and displays ionic conductivity. The overall mixture has a third phase-transition temperature for transitioning between liquid and solid states. This third phase-transition temperature is lower than the first and second phase transition temperatures.

Still other embodiments include those in which the gel includes a polymer network.

A single transistor of the type described herein is able to measure pressure within a limited range of pressures. This defines a dynamic range of the transistor. Because the transistors rely on a gel, a synergistic relationship arises when interconnecting transistors. In particular, it is possible to expand this dynamic range, thus allowing a set of interconnected transistors to measure pressures that would be beyond the ability of a single transistor to measure.

Embodiments thus include those in which the transistor is a first transistor that senses pressure within a first range of pressures, the apparatus further comprising a second transistor that has the same structure as the first transistor and that is connected to the first transistor to form a combination of transistors. This combination senses pressure within a second range of pressure. The first range is a proper subset of the second range. This expands the dynamic range of the first transistor. The extent to which it does so is defined by the complement of the intersection of the first and second ranges. Embodiments include those in which the first and second transistors connect in parallel and those in which they connect in series.

In other embodiments, the transistor is a first transistor that senses pressure within a first range of pressures. This first transistor is also one of a plurality of additional transistors, each having the same structure as the first transistor. The additional transistors and the first transistor are interconnected to form a combination of transistors, The combination senses pressure within a second range of pressure such that the first range is a proper subset of the second range. This expands the dynamic range of the first transistor in a similar manner.

In another aspect, the invention features a method for sensing pressure. Such a method includes obtaining information indicative of a change of capacitance caused by deformation caused by the pressure on a body that is coupled to a gate of a transistor, wherein the body includes a gel that includes a eutectic mixture having ionic conductivity. Among these gels are those that comprise a deep eutectic solvent gel.

Among the practices of the method are those in which the pressure acts on an artificial skin that includes a transistor array, one of which is the transistor.

Also among the practices of the method are those in which the body includes a pressure-sensing region and a gate region, the gate region being disposed adjacent to a gate of the transistor. In such embodiments, pressure acts on the pressure-sensing region of the body and obtaining the information includes detecting an effect of the pressure at a gate region of the body using long-range polarization of the gel.

In still other practices, obtaining the information includes sensing an electrical phenomenon that occurs on a conductive thread that forms an active channel of the transistor. An example of such a phenomenon is current passing through the active channel. Another example is a change in a current passing through the active channel.

These and other features of the invention will be apparent from the following detailed description and the accompanying figures, in which:

### BRIEF DESCRIPTION OF THE FIGURES

FIG. 1 shows a cross-section of a variable-capacitance transistor having an electrolyte gate;

FIG. 2 shows an equivalent circuit for the transistor shown in FIG. 1;

FIG. 3 shows gel protrusions of different heights;

FIG. 4 shows gel protrusions of different shapes;

FIG. 5 shows contact area as a function of applied weight;

FIG. 6 shows a transistor having a pressure-sensitive region of gel that is remote from the gate region of the gel;

FIG. 7 shows a parallel connection between transistors; and

FIG. 8 shows a series connection between transistors.

### DETAILED DESCRIPTION

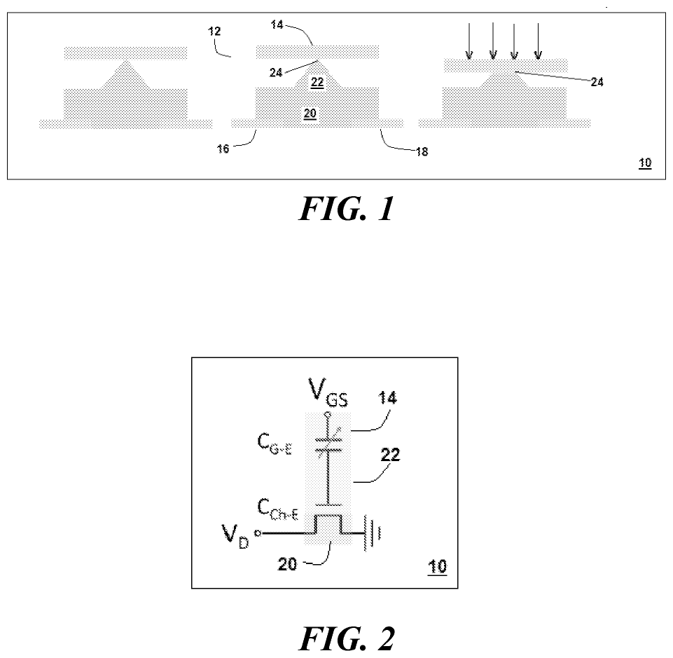

FIG. 1 shows an artificial skin 10 having a plurality of pressure-sensitive transistors 12, one of which is shown with pressure being applied thereto. Each such transistor includes a gate 14, a source 16, and a drain 18. An active channel 20 extends between the source 16 and the drain 18 and part of the way towards the gate 14. Between the active channel 20 and the gate 14 is a deformable protrusion 22 that contacts the gate 12 at a contact area 24.

The extent of the contact area 24 is variable. In response to pressure applied normal to the gate 14, the protrusion 22 deforms, as shown in the rightmost transistor in FIG. 1. In the illustrated embodiment, deformation causes the contact area 24 to increase with increasing applied pressure. This deformation results in a change in potential energy as a result of work done by the pressure applied to the gate 14.

FIG. 2 shows a circuit 26 that is equivalent to the transistor 12 shown in FIG. 1. The circuit 26 features a channel capacitance C_{CH-E} associated with the active channel 20 and a gate capacitance C_{G-E} associated with the protrusion 22. The gate capacitance C_{G-E} is a variable capacitance that depends on applied pressure. This enables the transistor 12 to modulate an electrically-measurable quantity in response to pressure.

The transistor 12 has an intrinsic sensitivity limit as a result of the relationship between the two capacitances shown in FIG. 2, with a roughly linear sensitivity arising when the capacitances are approximately equal. In particular, a sigmoidal relationship exists between voltage drop across the transistor 12 and relative capacitance changes between the interfaces.

The rate at which capacitances change depends on a variety of factors, including material properties, such as viscoelasticity and modulus, and the shapes of the various features of the transistor 12, such as the shape of the protrusion 22.

To circumvent the foregoing limitation, it is possible to combine active channels 20 in parallel or in series to extend the dynamic range in either direction. Connecting in series or parallel is easily carried out by directly attaching existing gels at active channels 20 or adding new gel precursor solution to form new pathways between active channels 20.

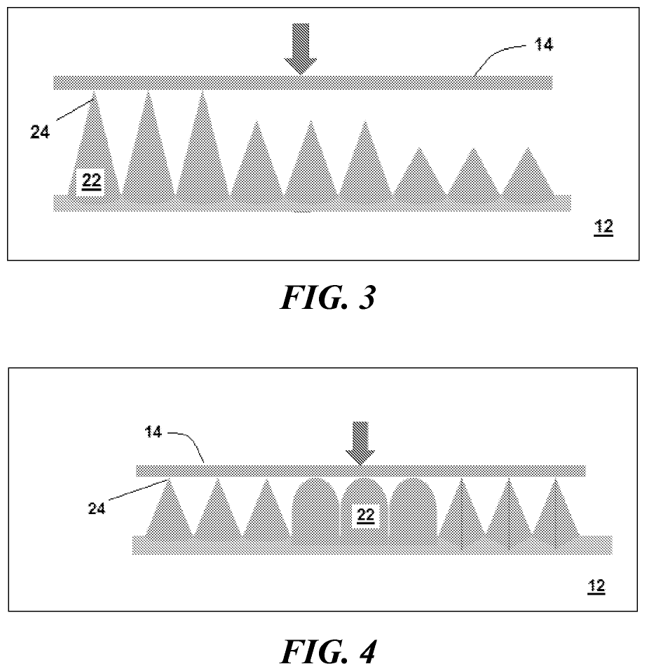

In an alternative embodiment, shown in FIG. 3, the gate 14 extends across several protrusions 22 of different heights. This provides a way to have different portions of the transistor 12 be sensitive to pressure by different amounts. For example, in FIG. 3, the leftmost portion of the gate 14 would cause a change of capacitance in response to pressure relatively quickly because the gate 14 is already in contact with the protrusions 22. In contrast, the rightmost portion of the gate 14 has to travel down by some distance before it contacts the protrusions 22. Since capacitance only changes once the protrusions 22 deform, this tends to delay the sensing of pressure.

FIG. 3 shows conical protrusions 22. FIG. 4 includes tombstone-shaped protrusions 22 along with conical protrusions 22. This causes different portions of the gate 14 to have different sensitivities.

Changing the shape or the size of the protrusions 22 changes the manner in which the contact area 24 between the gate 14 and the gel that forms the protrusion 22 changes in response to applied pressure. The use of gel as a material for the protrusion 22 is particularly advantageous because of its flexibility in accommodating different sizes and shapes of the protrusion 22 and its ability to conform to different shapes.

The protrusions 22 are easily manufactured by using an additive manufacturing process to print a mold of suitable shape and to simply pour a gel precursor into the mold and allow it to cool. In those cases, in which the transistor 12 is integrated into a thread, the above process can be seamlessly integrated into the manufacture of the required structure by applying additional gel precursor to connect a pressure-sensing gel remote from the transistor 12 to the transistor 12.

In contrast, using conventional dielectric materials to achieve the same effect would require complex lithographic techniques to form small and uniform features.

Other shapes are possible, such as hemispherical protrusions, conical protrusions, and pyramidal protrusions. In addition, there exist protrusions 22 that extend linearly in the manner of a speed-bump, with the cross-section of the linearly-extending protrusion being, for example, triangular or hemispherical. These different shapes differ in the rate at which contact area changes as a function of applied pressure. This, in turn, affects how quickly the capacitance changes in response to pressure.

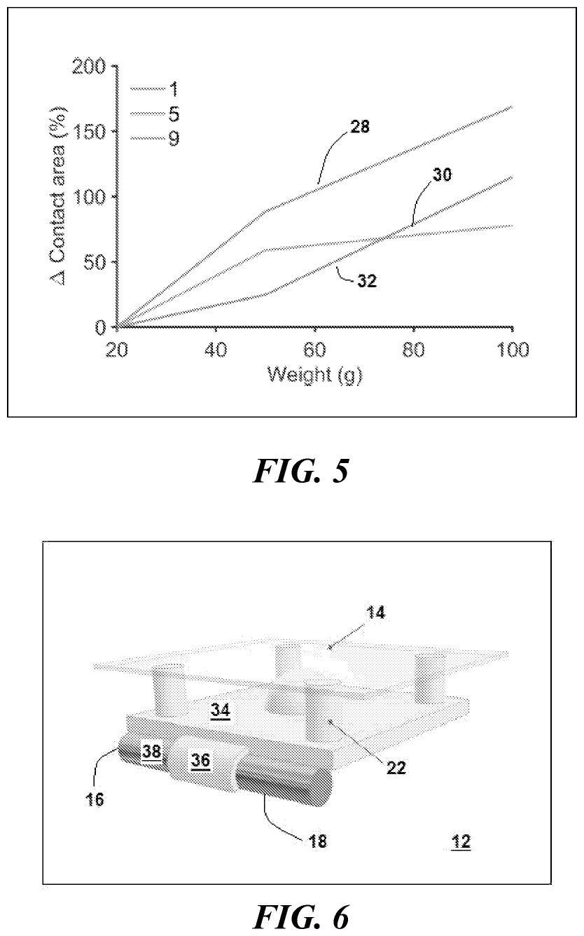

The manner in which the distribution of protrusions 22 changes capacitance is illustrated in FIG. 5, in which the abscissa shows applied weight and in which the ordinate shows contact area, which relates to capacitance.

A first curve 28 shows contact area as a function of applied weight for the case of single pyramid with a square base that is twelve millimeters on a side and protruding by five millimeters. A second curve 30 shows contact area as a function of applied weight for the case of five pyramids, each with a square base that is six millimeters on a side and each protruding by three millimeters. A third curve 32 shows contact area as a function of applied weight for the case of nine pyramids, each with a square base that is four millimeters on a side and each protruding by three millimeters.

In a preferred embodiment, the deformable protrusion 22 comprises a deep eutectic solvent gel. Such a gel offers high ion density, low volatility, moderate ion conductivity, and chemical tunability. Moreover, such a gel is typically made of less expensive and biofriendly components. In addition, a deep eutectic solvent gel promotes gelatin self-assembly, which provides unique mechanical properties to the protrusion 22. An example of such a gel is a mixture of quaternary ammonium salt, choline chloride, and a hydrogen bond donor. Examples include glycerol, ethylene glycol, and urea.

Other embodiments rely on a gel electrolyte, examples of which include an aqueous electrolyte, an organic electrolyte, ionic liquid, or a deep eutectic solvent. In some cases, a scaffold supports the gel. Examples of materials for making a scaffold include small molecules, polymers, nanoparticles, or combinations thereof.

Use of electrolyte rather than a conventional gate dielectric enables ultra-high touch sensitivity endowed by the formation of an electrolytic double layer upon contact between the electrolyte and the gate 14. This can result in several orders of magnitude change in capacitance, which in turn impacts the transistor's drain current. Use of an electrolyte also brings about a high volumetric gate capacitance, which in turn results in high transconductance even at low voltages. As a result, even small changes in voltages cause large changes in the transistor's drain current.

FIG. 6 shows a transistor 12 in which a continuous body of gel forms a pressure-sensing region 34 and a gate region 36. The gate region 36 surrounds a conducting fiber 38 that forms the active channel 20 between the source 16 and gate 18. Protrusions 22, which in FIG. 5 take the form of support pillars, extend upwards from the floor of the pressure-sensing region 34 to support the gate 14.

A pressure applied to the protrusions 22 changes the gel's electrical properties within the pressure sensing region 34. However, the electrolyte gel's long-range polarizability communicates the disturbance to the gel's electrical properties in the pressure-sensing region 34 to portions of the gel that are remote from the disturbance, and in particular, to the gate region 36. This permits placement of the pressure-sensing region 34 remote from the gate region 36. Moreover, this also makes it possible to manufacture the pressure-sensing region 34 and the gate region 36 separately and to later join them together by filling a gap between them with additional gel.

As noted above, it is possible for transistors 12 to share the gel and to thus be connected either in parallel or in series depending on which terminals are sharing the gel. Doing so changes the effective width or the effective length of the transistor 12.

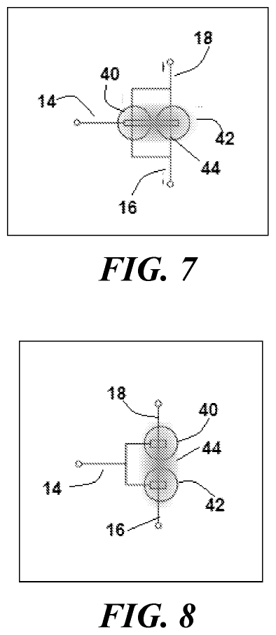

FIG. 7 shows a parallel connection between first and second transistors 40, 42 in which gel 44 connects the gates of the transistors 40, 42. This results in an effective width that is the sum of the widths of the transistors being combined.

FIG. 8 shows a series connection between first and second transistors 40, 42 in which gel 44 connects the active channels of the transistors 40, 42. This results in an effective length that is the sum of the lengths of the transistors 40, 42 being combined.

Having described the invention and a preferred embodiment thereof, what is claimed as new and secured by Letters Patent is:

1. An apparatus comprising a transistor having a capacitance that varies in response to pressure applied to said transistor, said transistor comprising a gel coupled to a gate of said transistor, the gel comprising a eutectic mixture having ionic conductivity.

2. (canceled)

3. The apparatus of claim 1, further comprising artificial skin that comprises a transistor array, wherein said transistor is one of a plurality of transistors in said transistor array.

4. The apparatus of claim 1, wherein said transistor comprises a gate electrode that is in contact with said gel and wherein pressure applied to said gate electrode deforms said gel, and wherein deformation of said gel changes said capacitance.

5. The apparatus of claim 1, wherein said transistor comprises a first capacitance and a second capacitance, wherein said first capacitance is a capacitance of an interface between a gate terminal and said gel, wherein said second capacitance is a capacitance of a conducting channel connected to a drain of said transistor, and wherein said first capacitance varies in response to pressure.

6. The apparatus of claim 1, wherein said transistor comprises a body of gel, wherein said body of gel comprises a pressure-sensing region and a gate region, wherein said gate region is coupled to said gate, wherein a force applied to said pressure-sensing region results in a change in an electrical characteristic at said pressure-sensing region, and wherein said change is communicated to said gate region as a result of long-range polarization of said gel.

7. (canceled)

8. The apparatus of claim 1, wherein said transistor comprises protrusions and wherein deformations of said protrusions in response to pressure applied to said protrusions change said capacitance.

9. The apparatus of claim 1, wherein said transistor comprises protrusions of different shapes and wherein pressure applied to said protrusions deforms said protrusions and changes said capacitance.

10. The apparatus of claim 1, wherein said transistor comprises protrusions of different heights and wherein pressure applied to said protrusions changes said heights and changes said capacitance.

11. The apparatus of claim 1, wherein said transistor comprises protrusions of different heights and shapes, wherein said protrusions deform at different rates in response to pressure applied to said protrusion, and wherein deformations of said protrusions change said capacitance.

12. (canceled)

13. The apparatus of claim 1, further comprising a conductive thread that extends between a source and drain of said transistor, wherein said conductive thread is coupled to said gate.

14. The apparatus of claim 1, wherein said gate is coupled to active channels of said transistor and wherein said active channels are connected in parallel.

15. The apparatus of claim 1, wherein said gate is coupled to active channels of said transistor and wherein said active channels are connected in series.

16. (canceled)

17. The apparatus of claim 1, wherein said transistor comprises a combination of poly (3, 4-ethylenedioxythiophene) and sodium polystyrene sulfonate.

18. (canceled)

19. (canceled)

20. (canceled)

21. (canceled)

22. The apparatus of claim 1, wherein said gel comprises a deep eutectic solvent gel.

23. The apparatus of claim 1, wherein said gel comprises a liquid component and a solid network that serves as a scaffold for said liquid component, wherein said liquid component comprises a mixture that comprises a first substance and a second substance, said first and second substances having corresponding first and second phase transition temperatures for transitioning between liquid and solid states, wherein said first substance comprises an ionic species and displays ionic conductivity, wherein said mixture has a third phase transition temperature for transitioning between liquid and solid states, and wherein said third phase transition temperature is lower than said first and second phase transition temperatures.

24. (canceled)

25. The apparatus of claim 1, wherein said transistor is a first transistor that senses pressure within a first range of pressures, said apparatus further comprising a second transistor that has the same structure as the first transistor and that is connected to said first transistor to form a combination of transistors, wherein said combination of transistors senses pressure within a second range of pressure, and wherein said first range is a proper subset of said second range.

26. The apparatus of claim 1, wherein said transistor is a first transistor that senses pressure within a first range of pressures, said apparatus further comprising a second transistor that has the same structure as the first transistor and that is connected to said first transistor in parallel to form a parallel combination of transistors, wherein said parallel combination of transistors senses pressure within a second range of pressure, and wherein said first range is a proper subset of said second range.

27. The apparatus of claim 1, wherein said transistor is a first transistor that senses pressure within a first range of pressures, said apparatus further comprising a second transistor that has the same structure as said first transistor and that is connected to said first transistor in series to form a series combination of transistors, wherein said series combination of transistors senses pressure within a second range of pressure, and wherein said first range is a proper subset of said second range.

28. The apparatus of claim 1, wherein said transistor is a first transistor that senses pressure within a first range of pressures, wherein said first transistor is one of a plurality of additional transistors, each having the same structure as the first transistor, said additional transistors and said first transistor being interconnected to form a combination of transistors, wherein said combination of transistors senses pressure within a second range of pressure, and wherein said first range is a proper subset of said second range.

29. A method comprising providing a body that comprises a gel that comprises a eutectic mixture having ionic conductivity and that is coupled to a gate of a transistor and sensing a pressure applied to said body, wherein sensing said pressure comprises obtaining information indicative of a change of capacitance caused by deformation caused by said pressure on said body.

30. (canceled)

31. (canceled)

32. (canceled)

33. (canceled)
